(19) United States
(12) Patent Application Publication
(10) Pub. No.: US 2015/0028084 A1
(43) Pub. Date: Jan. 29, 2015

(54) METHOD FOR CARRYING OUT SOLDER CONNECTIONS IN A TECHNOLOGICALLY OPTIMIZED MANNER

(71) Applicant: FEW FAHRZEUGELEKTRIKWERK GMBH & CO. KG, Zwenkau (DE)

(72) Inventor: Andre Jenrich, Zwenkau (DE)

(73) Assignee: FEW FAHRZEUGELEKTRIKWERK GMBH & CO. KG, Zwenkau (DE)

(21) Appl. No.: 14/378,501

(22) PCT Filed: Feb. 21, 2013
(86) PCT No.: PCT/EP2013/053458

§ 371 Date: Aug. 13, 2014

(30) Foreign Application Priority Data
Feb. 24, 2012 (DE) 102012003804.6
Apr. 18, 2012 (DE) 102012007804.8

(51) Int. Cl. B23K 1/00; B23K 1/20; H01L 23/00

(52) U.S. Cl. CPC B23K 1/0016; H01L 24/83; B23K 1/203; H01L 2224/83815; H01L 2224/8321
USPC 228/122.1; 228/214

(57) ABSTRACT

The invention relates to a method for carrying out solder connections in a technologically optimized manner, in particular lead-free solder connections. At least one of the joining partners provides the solder required for the connection. A flux is used in order to activate the solder, and the electric and mechanical connection is carried out by means of a soldering process under the effect of heat and by melting the solder/flux mixture with the inclusion of a subsequent cooling phase. According to the invention, the joining partners and the solder are heated to a temperature below the activation temperature of the solder and the flux in a first temperature treatment phase. Another heating process is then carried out to a temperature above the activation temperature of the flux up to the upper melting range of the solder in a second temperature treatment phase, wherein the solder melts and begins to connect to the respective joining partners. Furthermore, the thermal output previously applied is increased by an additional 5% to 30% in a third temperature treatment phase in order to accelerate the adhesion behavior of the joining partners.

The invention relates to a method for the technologically optimized execution of solder connections, particularly lead-free solder connections, wherein at least one of the mating parts provides the solder necessary for the connection, a flux is used to activate the solder, and the electrical and mechanical connection is realized by a soldering process using the action of heat and melting of the solder/flux mixture, including a subsequent cool-down phase, according to claim 1.

A method for the purpose of improving the quality of solder connections is known from DE 102 03 112 A1. In this approach, large-surface SMD components are soldered to wire harnesses, wherein the mating parts are electrically and mechanically connected to each other by fusion soldering. A flux is used to activate the solder.

DE 102 03 112 A1 brings attention to the problems associated with the organic components of the solder paste. Components which are not consumed in the chemical activation of the mating parts can disperse during the soldering process in and around the solder connection. The organic components remaining inside the solder connections, once formed, form bubbles filled with liquid or steam during the soldering process, and rise into the upper regions of the solder connection due to their buoyancy. As a result, the bubbles meet the mostly flat component connections or the flat areas of the component undersides when passing through a soldering furnace, depending on the position of the component. Such bubbles lead to failure points in the solder contact—meaning that the electrical and mechanical function of the solder connection is compromised. In order to prevent this disadvantageous occurrence, the design of the mating parts can be modified by, for example, modifying the shape and the position of a solder paint around the joint in order to prevent a collection of the bubbles as they arise. An attempt has also been made to implement a change in the melting profile, wherein a slower or faster increase in the temperatures, and a change in the peak temperature, give the bubbles time to rise and to exit the metal melt laterally. However, the increased thermal load on the components is disadvantageous in this case.

For the purpose of improving the quality of solder connections, DE 102 03 112 A1 discloses the approach of transitioning the mating parts, at least during the melting process of the solder paste, into a prespecified tilt angle with respect to the normal. Moreover, the mating parts should be transported multiple times through a soldering furnace.

With respect to the reduction of the number of failure points, the above measures demonstrate improvements, but nevertheless complicate the technological sequence, while the cycle time of the corresponding soldering process grows longer.

For electrical connections which are soldered to a glass glaze, and particularly automobile glass glaze, the use of copper materials has been relied on to date. Copper materials as the connection element, however, have the disadvantage that the expansion thereof upon a change in temperature is different than that of the glass as a result of the corresponding coefficients of expansion.

The resulting mechanical stress can lead to breaks in the glass. These disadvantageous effects have been compensated to date by the use of special, ductile, lead-containing solder alloys. However, demands are increasing to dispense with the use of lead, and to use lead-free solders in particular. This, however, creates technological problems.

Materials which have a coefficient of expansion similar to vehicle glass, including iron-nickel alloys and stainless steel, can naturally be contemplated. The heat conductivity of these materials, however, is significantly poorer than that of copper. The heating of an electrical connection made of, for example a nickel alloy, including the solder alloy, therefore requires a greater amount of time for the cycle and/or more heat energy.

This results in a heat transport damping effect—meaning that the energy proceeding from the heat source is passed to the heat sink, which is the solder and the corresponding contact surface on the pane, significantly more slowly.

Moreover, the liquid point of lead-free alloys is significantly lower, at approx. 120° C. to approx. 170° C., than that of lead-containing alloys, which is in the range between 200° C. and 300° C.

Therefore, as a result of the above, there are greater inputs when [lead-free] soldering processes are carried out, including greater energy input, longer work time, and as a result, a limitation of the machine capacity. Finally, there is a risk of glass breakage which is also significant. Also, it has been shown that the sensitivity of the glass conventionally used in the automotive field to breakage when subjected to higher temperature changes limits the possibility of using the obvious measure of increasing the heat energy—that is, of using accordingly greater power.

In addition, lead-free solders bond significantly more poorly with the conductive contact surfaces conventionally applied to the glass material—for example in the form of a silver print. It is difficult to form solder fillets, and there is the risk that the solder pops, or solder pearls form, which in turn leads to a reduced electrical and mechanical strength between the mating parts.

Therefore, proceeding from the above, the problem addressed by the invention is that of providing an advanced method for the technologically optimized execution of solder connections, particularly lead-free solder connections, wherein at least one of the mating parts provides the solder necessary for the connection, a flux is used to activate the solder, and the electrical and mechanical connection is realized by a soldering process using the action of heat and melting of the solder/flux mixture, including a subsequent cool-down phase, wherein the risk of a glass break in this case is also reduced, and it is possible overall to avoid an increase in the solder cycle time compared to methods used to date.

The problem addressed by the invention is solved by a teaching according to claim 1, wherein the independent claims constitute, at the very least, advantageous embodiments and implementations.

In the method according to the invention for the technologically optimized execution of solder connections, and particularly lead-free solder connections, at least one of the mating parts provides the solder necessary for the connection. This is realized, by way of example, by a lead-free solder having been previously applied to an end sleeve or a solder foot. In addition, a flux is used which is already contained in the solder, or which can be applied separately.

The actual solder connection is realized by a soldering process using the action of heat and melting of the solder/flux mixture, with a subsequent cool-down and solidification.

According to the invention, the mating parts and the solder are heated in a first temperature treatment phase to a temperature below the activation temperature of the solder and the flux.

A second temperature treatment phase follows the above, wherein a further heating is carried out to a temperature above the activation temperature of the flux, into the upper region of the melting range of the solder. In this step, the solder melts and begins to bond to the respective mating parts.

In addition, for the purpose of accelerating the adhesive behavior of the mating parts during the soldering process, an increase in thermal power or energy applied up to this point is carried out in the third temperature treatment phase, by a further 5% to 30%.

One of the mating parts is a metallic surface applied to a glass material, particularly a silver print contact surface, for example for a defrosting heater connection or antenna connection of a motor vehicle.

Another of the mating parts is an electrical connection agent, preferably consisting of an iron-nickel alloy. End sleeves, solder straps, or solder feet can be used as the electrical connection means. An end sleeve according to DE 20 2008 015 165 U1 is a preferred electrical connection means. The disclosure in DE 20 2008 015 165 U1 is therefore named as a part of the present teaching. The same applies for the disclosure according to DE 20 2011 100 906 U1.

The temperature range of the first treatment phase is substantially between 80° C. and 120° C. in a preferred embodiment. The temperature range of the second temperature treatment phase is substantially between >120° C. and 200° C. in a preferred embodiment.

The temperature treatment phases above end when there is an even formation of solder fillets, and/or the same can be seen, between the mating parts.

The teaching according to the invention serves the purpose of improving the adhesion of the solder to the silver print contact surface, and reduces the stress of the base material—meaning the glass—when exposed to abrupt temperature changes.

The invention is described below in greater detail with reference to an embodiment and to figures, wherein:

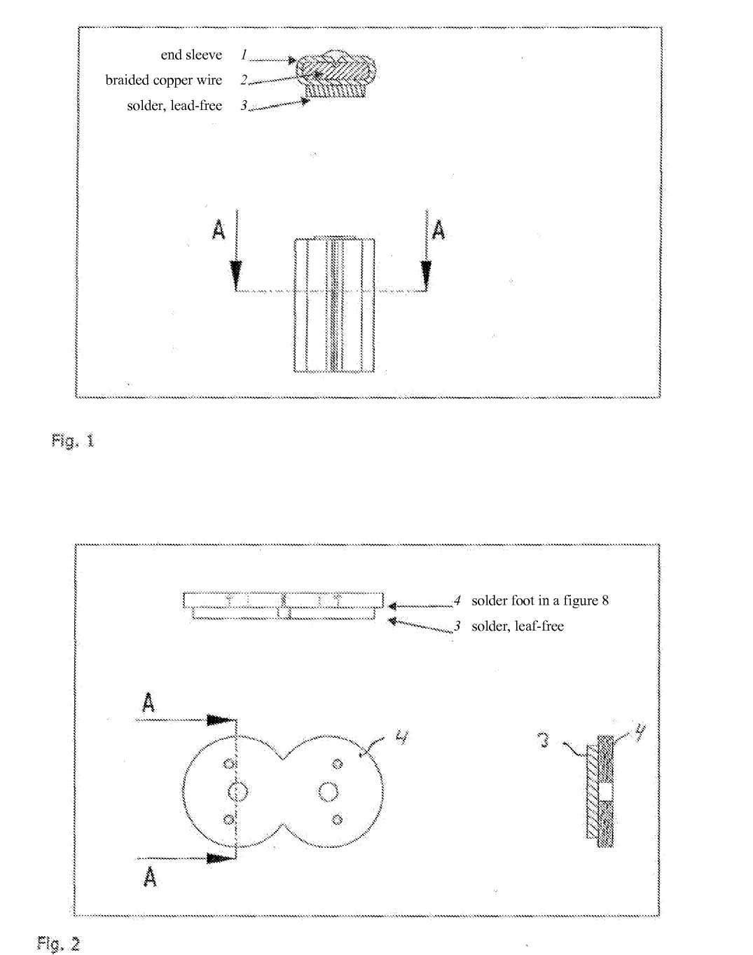

FIG. 1 shows an exemplary cross-section and a top view of a cable end having an end sleeve as an exemplary mating part, wherein the cable end is a braided copper wire which is pressed to the end sleeve, wherein a flank of the end sleeve also has a coating of lead-free solder;

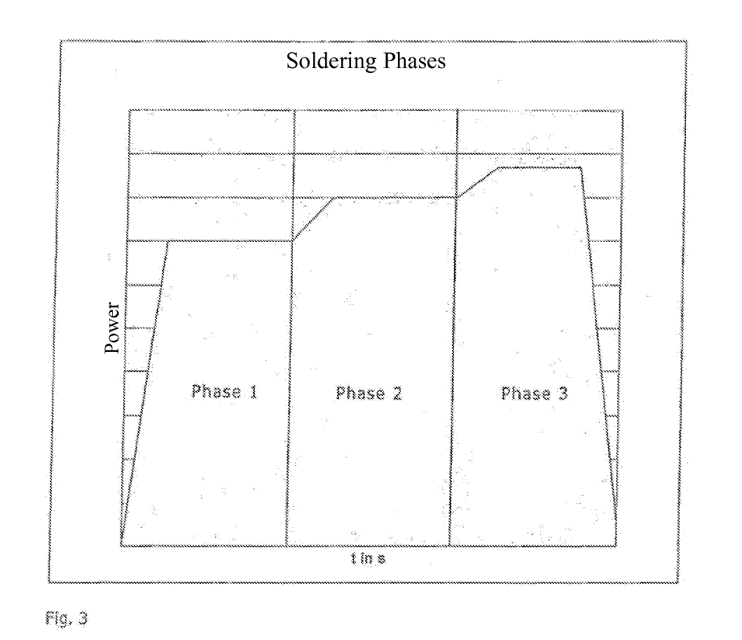

FIG. 2 shows a side view and a top view of a soldering blank in the shape of a FIG. 8, including a lead-free solder coating present on the underside of the solder foot, as well as a cutaway view along the line A-A, and

FIG. 3 shows a diagram of the power and/or energy profile over time, with the three temperature treatment phases, including a rapid cool-down process at the end of phase 3.

End sleeves 1 according to FIG. 1 can be used as the mating parts. The end sleeves 1 receive an uninsulated braided copper wire end 2 of a cable which is not shown in the figure. The braided copper wire 2 is preferably connected to the end sleeve 1 by means of crimping.

There is a layer of lead-free solder 3 on a lower flank of the end sleeve 1.

On the mating part, designed as a solder foot in the shape of a FIG. 8 (reference number 4) in FIG. 2, there is likewise a layer of lead-free solder 3 on the underside of the solder foot 4.

The end sleeves, for example as antenna connectors according to FIG. 1, can be implemented according to the teaching in DE 20 2008 015 165 U1. The connectors in the form of a solder foot 4 according to FIG. 2 can be designed according to the teaching of DE 20 2011 100 906 U1.

The three essential phases of the soldering process, as illustrated in FIG. 3, proceed as follows.

In a first phase, the electrical connector, the solder, and the silver print applied to the corresponding glass pane are heated to below the activation temperature of the flux, and above the temperature point at which the solder begins to become liquid. The system is thereby evenly heated without the flux liquefying.

In a second phase, the system is heated to a temperature which is above the activation temperature of the flux and the upper region of the melting range of the solder.

The flux is thereby activated and dissolves the oxidation layers on the silver print and the solder itself The solder becomes liquid and begins to bond to the alloy of the silver print.

In the third phase, an increase in the application of power is carried out according to the invention by a further 5% to 30% in order to accelerate the adhesive behavior of the mating parts.

The thermal treatment period then ends when solder fillets have formed evenly.

According to one embodiment of the invention, the duration of the first phase is in the range of 0.5 to 3 seconds, the duration of the second phase is in the range of 0.5 to 4 seconds, and the duration of the third phase is in the range of 0.5 to 5 seconds. In one preferred embodiment, phase 1 runs over a period of approx. 1.5 to 1.8 seconds. The second phase follows, in the time period with respect to the starting time point—meaning the start of the first phase—from >1.5 to 1.8 seconds to approx. 6 seconds. The subsequent third phase then begins after the 6 seconds runs out, and lasts until 8.5 seconds.

The power profile of the first phase is in the range between 150 and 350 Watts, the power profile of the second phase is in the range between 160 and 400 watts, and the range of the third phase is between 170 and a maximum of 500 Watts.

1. A method for the technologically optimized execution of solder connections, particularly lead-free solder connections, wherein at least one of the mating parts provides the solder necessary for the connection, wherein flux is used for the purpose of activating the solder, and wherein the electrical and mechanical connection is realized by a soldering process using the action of heat and melting of the solder/flux mixture, including a subsequent cool-down phase, wherein the mating parts and the solder are heated in a first temperature treatment phase to a temperature below the activation temperature of the solder and the flux, subsequently, a further heating to a temperature above the activation temperature of the flux takes place in a second temperature treatment phase, into the upper end of the melting point range of the solder,
wherein the solder melts and begins to bond to each of the mating parts, and
for the purpose of accelerating the adhesive behavior of the mating parts, thermal power or energy applied up to this point in time is further increased by an additional 5% to 30%, in a third temperature treatment phase.

2. A method according to claim 1,
wherein one of the mating parts is a metallic surface applied to a glass material, and is particularly a silver print.

3. A method according to claim 1,
wherein another of the mating parts is an electrical connecting agent, consisting of an iron-nickel alloy.

4. A method according to claim 3,
wherein end sleeves, solder straps, or solder feet are used as the electrical connection means.

5. A method according to claim 1, wherein the temperature range of the first treatment phase is between, substantially, 90° and 120° C., and the temperature range of the second temperature treatment phase is between >120° C. and 200° C.

6. A method according to claim 1, wherein the third temperature treatment phase ends when an even formation of solder fillets can be recognized between the mating parts.

7. A method according to claim 1, wherein the temperature treatment phases include a temperature hold phase.

8. A method according to claim 2, wherein another of the mating parts is an electrical connecting agent, consisting of an iron-nickel alloy.
